(19) United States
(12) Patent Application Publication
(10) Pub. No.: US 2001/0049213 A1
(43) Pub. Date: Dec. 6, 2001

(54) ELECTRICAL CONNECTOR WITH FLOATING TERMINALS AND TERMINAL THEREOF

(76) Inventors: PAUL J.M. POTTERS, EINDHOVEN (NL); ALBERTUS VAN ZANTEN, HERTOGENBOSCH (NL)

Correspondence Address: BRIAN J HAMILLA, FCI BERG ELECTRONICS GROUP INC, 825 OLD TRAIL ROAD, ETTERS, PA, 17319

(21) Appl. No.: 09/215,028

(22) Filed: Dec. 17, 1998

(30) Foreign Application Priority Data
Dec. 17, 1997 (EP) 97203979.6

(51) Int. Cl. H05K 1/00

(52) U.S. Cl. 439/80

(57) ABSTRACT

A connector having a mating side (26; 26″) and a rear side (27; 27″) opposing said mating side, provided with at least one cavity (1; 1″) accommodating a terminal (2; 2″), said terminal having a mating portion (8; 60) for mating contact with another terminal of another connector, an intermediate, at least partly flexible portion (14; 14″) connected to said mating portion (8; 8″), a terminal retention portion (16; 16″) connected to said intermediate portion (14; 14″), and a contact portion (45; 45″) connected to said retention portion (16; 16″), said at least one cavity (1; 1″) fixedly accommodating said terminal retention portion (16; 16″) wherein that said cavity (1; 1″) has a cavity retention portion (31; 31″) securing said terminal retention portion (16; 16″), said cavity retention portion (31; 31″) having a cross section comprising a first opening (29; 29″) sized for freely passing said mating portion (8; 8″) during stitching said terminal (2; 2″) into the cavity (1; 1″), and a second opening (28; 28″) sized for fixedly accommodating said terminal retention portion (16).

### BACKGROUND OF THE INVENTION

1. Field of the Invention

The present invention relates to electrical connectors. More specifically, the present invention relates to electrical connectors adapted to accommodate misaligned contacts from the mating connector.

2. Brief Description of Earlier Developments

One major problem in the connectors industry is to provide mating receptacle and plug connectors which can be connected to one another despite some misalignment of some or more pins of the plug connector. Therefore, ideally, there is some space between a receptacle terminal and its housing cavity to allow a receptacle terminal to “rock” and to align, or center the receptacle terminal on a theoretically “misaligned” pin of a mating plug connector such that the normal force from the two beams of the dual-beam contact on opposite sides of the pin are equal to allow a force equilibrium. In order to deal with the problem of misaligned pins of a mating plug connector, several earlier developments have proposed to provide “floating” dual-beam contacts within the cavity.

U.S. Pat. No. 4,966,557 describes such a connector. This document discloses a box-shaped receptacle contact with U-shaped cross section whereby the receptacle contact has two floating contact beams within the cavity of the connector housing. The two contact beams of the receptacle contact are supported by a flexible hinge which is supported by a U-shaped retention section which is fixedly accommodated within the cavity of the connector housing. The provision of a U-shaped retention section prevents the terminal from rotation within the cavity. However, no measures are taken to define the depth of insert of the terminal into the cavity during manufacturing the connector: along its entire length the cavity has equal dimensions. Moreover, the U-shaped retention portion is relatively large and is unsuitable for further miniaturization. Furthermore, when several adjacent cavities are accommodating such terminals with U-shaped retention portion, relatively large metallic surfaces of adjacent terminals are rather close to one another resulting in a too high level of cross talk at higher frequencies.

U.S. Pat. No. 4,934,967 describes a receptacle terminal with a circular cross section and which is movable within the cavity of the connector housing is shown in. The pin receiving portion of the receptacle terminal is supported by a flexible hinge, which itself is supported by a retention portion which is fixedly accommodated within the cavity of the connector housing. The retention portion is circular shaped and contacts a large amount of the circular shaped cross section of the cavity. This connector has the same disadvantages has the connector described in U.S. Pat. No. 4,966,557 discussed above.

U.S. Pat. No. 5,334,035 describes a floating receptacle contact with a circular cross section. The receptacle contact is provided with an annular bead which is received by a bearing support with an annular groove in the cavity of the connector housing. In an alternative embodiment, the receptacle contact is provided with an annular groove which is supported in an inwardly curved annular bead of the cavity of the connector housing.

The terminal in U.S. Pat. No. 5,334,035 is difficult to produce and unsuitable for miniature applications. Moreover, the entire terminal is stiff, thus, when moving the mating portion the contact portion extending from the rear side of the connector also moves which, in miniature applications, is highly undesirable. U.S. Pat. No. 5,112,233 and European Patent number 0,488,349, for example, describe connectors with tuning fork type terminals of which the tuning fork type receptacle portion is oriented in a direction 90° bent relative to the orientation of the tail portion of the terminal. The connectors shown in these references are right-angle connectors. In other words, the contact portions of the terminals for connecting the connectors to a printed circuit board or the like are bent through 90° relative to the axis of symmetry of the cavities of the connector housing.

The connector housing is provided with a comb-like structure at its bottom face with a plurality of open faced slots with parallel, straight side walls for retentive receipt of the bent contact portions of the terminals therein. The bent portions of the contact portions are provided with sharp barbs.

During insertion of the terminals into the cavities of the connector housing, the bent contact portions are inserted into the open faced slots and the barbs engage the respective side walls in an interference fit in order to fixedly accommodate the bent contact portions of the terminals. Thus, in such a way a resistance to movement of the contact portions in both the horizontal and vertical directions is provided.

Each of the tuning fork type receptacle portions is provided with two tines for receipt of a mating pin-type terminal. The tip portions of the tuning fork type receptacle portions are slightly movable within the cavity of the connector housing. However, in both references, the rear sides of the tuning fork type receptacle portions are provided with barbs in order to securely accommodate the rear side of the tuning fork type receptacle portions within the respective cavities.

Dual beam spring contact receptacles have found wide use in the connector industry. Such dual spring elements can be extensions of a “U”shaped box, or may extend from a flat stock as with tuning fork type terminals.

Box-type contact terminals avoid problems of contact surface roughness since the contacting surfaces are usually along the mill-rolled plane of the material used to manufacture the terminals. These surfaces have usually low roughness. Preferably, the dual-beam contacts are oriented in the housing such that the spring deflection members are displaced during mating in a direction parallel to the plane containing a vertical column of contacts. Contrary to this, should tine deflection of the element occur along the direction of the connector length as a result of connector shrink or housing length tolerance (as might happen with relatively long connectors), this may easily result in that an individual pin contacts only one tine of the mating receptacle terminal. This inadvertently results in overstress of this particular tine of the receptacle terminal, a situation which is considered to be highly undesirable in many connector applications.

Ideally, a contour roughness as low as possible is required for the contacting surfaces of the receptacle terminal. Such a pre-requisite favors the use of box-type dual beam contacts. Moreover, the contact stiffness with cantilever beam loading perpendicular to the contact width, as with boxtype dual beam contacts, is substantially lower than the contact stiffness of a tuning fork type terminal with the same beams where loading is perpendicular to stock thickness. The contact surface roughness of cantilever beams is lowest along the material (mill) rolling surface. This contact surface roughness is much lower than the contact surface roughness of a (fractured) stamped edge of the beams of, say, the tuning fork contact. Again, this favors the use of the cantilever beam box contacts.

When using box-type dual beam contacts, adjacent contacts are close to one another resulting in “noise” cross-talk from adjacent signal positions in the connector at frequencies of 2 GHz and above.

When using contact material of typically 0.2 mm stock thickness, as required by a box-type of contact, the tail portions of the receptacle terminals also have a thickness of 0.2 mm. This results in additional problems during manufacture and application of the connector to a printed circuit board. In right-angle applications, this relatively flexible tail needs to be bent through 90° for connector mounting to the printed circuit board. Due to materials “history” and batch-to-batch variations in spring-back, a large variation in resultant tail tip true-position can be anticipated after the 90° bending.

Moreover, for press-fit applications to the printed circuit board, a tooling/mandrel needs to be integrated with the connector to push on the press-fit terminals by shoulders to carry out the connector application on customer printed circuit boards. For this purpose, usually a press block is pushed over the assembled and right-angle bent tails of the connector terminals. The function of this press block in right angle applications is two-fold: first, to ensure that the true-position of the tails is maintained within acceptable tolerances and second, the press block is a means to apply, in press-fit applications, the mass application force necessary to undertake press-fit insertion of terminals in the printed circuit board. In contrast, a wafer may be used only to correct for tail true position. Use of such a wafer or press-block and its assembly contribute to a substantial cost increase of the connector. The future trend is to use gold-plated through holes in printed circuit boards. Tests with gold-plated through holes in printed circuit boards have shown that the maximum pin insertion force of press-fit contacts needs to be limited to 40 N per press-fit terminal. The specific pressure exerted by the press-block wall on press-fit terminal shoulders, the terminal being limited to a thickness of 0.2 mm, with an applied insertion force of 40 N per press-fit terminal, results in press-block wall deformation. Consequently, in such extreme applications, the press-fit terminals are not fully inserted in a printed circuit board hole. Moreover, when using such 0.2 mm thin terminal material the use of a press-fit eye-of-needle contacts results in a higher stress distribution in the plated through hole increasing the possibility of rupture of the hole wall. An increase in press-fit board retention forces, as required, is difficult to be realized with this material thickness. Also, such thin 0.2 mm material easily aids buckling force limitation and a possibility to overstress the compliant press-fit section. As a solution one could use a thicker (pre-milled) strip material for the press-fit area only; however, this is not cost-effective.

An other option is to locally thicken the press-fit section of the terminal. However, in both cases, the resultant is an increased press-fit insertion force which needs to be withstood by the plastic walls of the press-block housing walls in an area of metal terminal shoulder, having a thickness of 0.2 mm. As a consequence of this, the local pressure exerted on the walls in the load bearing area is too high. This results in a local rupture or collapse of the press block wall preventing the insertion of a press-fit portion in the printed circuit board to the correct depth. U.S. Patent application Ser. No. 08/804,717, which is assigned to the proprietor of the present invention and which has not been disclosed prior to the date of priority of the present invention, describes a header right-angle connector with pin terminals. The problem solved by this application is the provision of enhanced true position tail location at low manufacturing costs. The header comprises two parts that are connected together, i.e., a press block and a shroud. The press block accommodates the pin terminals and is designed such that it can be used for fitting the right-angle connector to a printed circuit board or the like without the need for an additional press block.

The shroud is designed to cooperate with a mating receptacle connector. In an embodiment, the cavities are shown to have a substantially cruciform shape in cross section for securely accommodating the pin terminals. However, a first opening of this known cruciform shape is to accommodate the width of a pin terminal, whereas a second opening is shaped to prevent scratching of gold plating on the pin terminal contact faces. The side walls of the cavities may be bevelled inwardly to the centre of the cavity to establish a firmer clamping.

### SUMMARY OF THE INVENTION

It is an object of the present invention to provide an improved electrical connector.

It is a further object of the present invention to provide an electrical connector adapted to accommodate a misaligned pin of a mating connector.

The present invention relates to a connector having a mating side and a rear side opposing said mating side, provided with at least one cavity accommodating a terminal, said terminal having a mating portion for mating contact with another terminal of another connector, an intermediate, at least partly flexible portion connected to said mating portion, a terminal retention portion connected to said intermediate portion, and a contact portion connected to said retention portion, said at least one cavity fixedly accommodating said terminal retention portion.

The present invention is directed to providing a connector which may be used at 2 GHz and above, in which at the same time the problems of “misalignment” with mating terminals of a mating connector have been solved, and in which the need for using a press block may be absent. To this end, the present invention claims a connector characterized in that said cavity has a cavity retention portion securing said terminal retention portion, said cavity retention portion having a cross section comprising a first opening sized for freely passing said mating portion during stitching said terminal into the cavity, and a second opening sized for fixedly accommodating said terminal retention portion.

The terminals may be stitched either from the rear side or from the mating side. An advantage of stitching from the mating side into the cavity could be access for single terminal reparability for expensive backplanes, instead of the need to fully remove a full connector and thus potentially damage or destroy adjacent circuitry. If mating side terminal entry during stitching is a must, both the terminal and the housing cavity must be designed accordingly.

The application of floating mating portions within the cavities provides an adequate solution to the problem of misalignment. In order to fixedly accommodate the terminal retention portion within the cavity, each cavity is provided with a first opening and a second opening. The first opening is sized such that the mating portion of the terminal can freely pass it during terminal stitching from the rear side of the connector. The second opening is sized such that it will firmly grip the retention portion of the terminal. The first and second openings may be easily dimensioned such that the receptacle terminal has equal thickness at any location.

No additional thickening of the retention portion or thinning of e.g. the tines of the tuning fork is necessary to allow the mating portion to pass the first opening without any additional force. The retention portion may, e.g., be substantially flat, thus, increasing the relative distance to retention portions in adjacent cavities when compared with the relatively large retention portions of the prior art. Thus, not only does the housing wall become stronger in this direction, but also cross-talk can be reduced. Sometimes it is desirable to arrange the mating portion of the terminal in a rotated orientation with respect to the contact portion. This can easily be done by providing the intermediate portion with a first twist about a first angle. Alternatively, the intermediate portion may comprise a fold section with a fold about a predetermined first angle. The first angle may, e.g., be 45° or 90° .

When the first angle is 90°, then, the cross section of the first and second openings may have the shape of a cruciform or a “T”. Making this angle 90° has some additional advantages. The contact portion at the rear side of the terminal may e.g. be a pin contact of which the smooth mill-rolled contact sides are, then, rotated 90° relative to the main side surfaces of the receptacle portion at the front side of the terminal. Such a pin terminal can then be used for contacting a mating receptacle terminal of another connector since it has the proper orientation and thickness in relation to the receptacle gap between contact domes of such a mating receptacle terminal.

As explained above, the terminal comprises a neck portion between the mating portion and the retention portion. The neck portion may be flat or have a twist. In both cases, the neck portion of the terminal remains flexible to freely permit re-alignment of the actual mating portion, within the housing cavity, to adapt to an opposing contact terminal. However, a twist of the terminal within the cavity need not necessarily be within the neck portion.

Instead of or in addition to providing a rotation within the flexible, intermediate portion, the retention portion may comprise a second twist about a predetermined angle of, e.g., 45° or 90°.

The thickness of the terminal material may be in the range of 0.25 to 0.6 mm, typically in the order of 0.5 mm, which would give the following benefits:

a relatively thick terminal material thickness of typically 0.5 mm renders the possibility of a thicker press-fit section which, when inserted into a plated through hole of a printed circuit board, permits an increase in board retention force, as desired; with such a thicker press-fit section, it is possible to have all kinds of press-fit types, including H-shape and eye-of-a-needle;

in right-angle applications, due to the use of a larger stock thickness, material in bending zones of the right-angle are “plastically” deformed giving less spring-back, which ultimately results in an improved true position of the contact portion avoiding the necessity of using an additional press block;

in right-angle applications, the contact portions of the terminal extending transverse to the direction of the axis of symmetry of the cavities of the connector housing are stiffer, such that they will not buckle at higher press-fit insertion forces;

instead of a press block the top surface of each cavity in the connector housing may be used as a mandrel for press-fit pin insertion;

a material thickness of typically 5 mm provides the possibility of a rear plug-up section in the contact portion, extending beyond a printed circuit board for connection to a receptacle connector.

The arguments to favour the use of thicker stock material need to be analyzed and balanced on the design merits and capability of the receptacle terminal in its entirety. In other words, there should be a justification for the additional material cost associated. Investigations show that the additional material cost is easily offset by the gain in cost elimination for the wafer or press block. Moreover, higher specified press-fit retention forces are envisaged (quality improvement), as well as reduced quality rejects during manufacturing and ease in connector application on customer printed circuit boards. In addition, there is the possibility of mass-insertion row-by-row which reduces production costs with flexibility in product design and application.

With regard to the housing, the second opening may be provided with a bottom wall which is slightly inclined with respect to the axis of symmetry of the cavity such that the cross section dimension of the second opening reduces inwardly from the rear side of the connector housing. Such an inclination results in a higher retention force of the terminal retention portion when the terminal is inserted deeper into the connector cavity.

The retention force may be further enhanced by providing the terminal retention portion with at least one barb. Such a barb protruding beyond the plane of the terminal member will dig into the opposing cavity sidewall. It needs to be noted that, with this type of terminal stitching in the cavity from the rear side, the retention is provided towards the rear position of the connector. The reaction force of this retention provided by the barbs acts along the direction of the connector height, i.e., in the direction of a column of the connector. Since the cavity walls in the column direction are usually relatively thick these walls permit easy acceptance of this force without undue overstress of the connector walls.

Also the retention barbs push a flat surface of the terminal against the cavity ceiling as a reference. Because of this direction of the retention stress application, the stress along the length of the connector, i.e., the row direction, in which direction the walls are thinnest, is thus minimized. This feature contributes towards preventing product length growth of fully assembled connectors which would also complicate end-to-end module stackability. It is important to prevent such growth.

The contact portion may be selected from the following set of contact types: press-fit contact, solder through-mount contact, hold-down contact, surface-mount contact, wire-wrap contact, pin contact.

The contact portion and the board mounting side may extend in a direction perpendicular to the axis of symmetry of the cavity, thus forming a right-angle connector. In such an embodiment, the connector may be provided with an open rear side inclined substantially 45° with respect to the mating side, the housing being provided with a plurality of cavities arranged in columns and rows. In such an embodiment, each of the terminals have a tail portion extending within the cavities of the connector housing perpendicular to the direction of insertion of the contact portions into the printed circuit board. Thus, when inserting the contact portions into a printed circuit board, the top walls of the cavities may be used as a mandrel to insert the contact portions into the plated through holes of the printed circuit board (hence this design avoids the use of additional press block).

It will be appreciated that the insertion forces are relatively high. This may be undertaken without the necessity of using a separate tool or mandrel. Moreover, using an open rear side of the connecting housing offers the possibility of checking the quality of the electrical connections to the printed circuit board after assembly. Hence, besides avoiding the use (and also cost) of a press block, clear inspectability is an advantage.

The connector need not be a right-angle connector. Alternatively, the contact portion may extend in a direction parallel to the axis of symmetry of the cavity and the terminal may be provided with at least one lobe extending in a direction perpendicular to the axis of symmetry and abutting the rear side of the connector. Thus, the lobe can be used to define the depth of insert of a terminal into a cavity. Of course, other means for defining the depth of insert of a terminal into a cavity may be applied.

There is a growing need to have contacts which extend beyond a printed circuit board when inserted into a plated through hole. The portion extending beyond the printed circuit board can then be used e.g. for wirewrap application or as a pin contact for contacting a further receptacle connector in a plug-up relationship. Thus, in an alternative embodiment of the present invention, the terminal of the connector is provided with a contact portion, comprising a first contact section and a second contact section, the first contact section being connected to the tail portion and selected from the following group of contact types: press-fit contact, solder through-mount contact, hold-down contact and surface-mount contact, and the second contact section being connected to the first contact section and being selected to be either a pin contact or a wire-wrap contact.

The mating portion of the terminal may have any conventional shape but is, preferably, either a pin-type portion or a tuning fork type portion.

Moreover, the present invention is directed to a terminal having a tuning fork type receptacle portion, a terminal retention portion connected to said receptacle portion and to be fixedly accommodated by a cavity retention portion of a connector as claimed in any of the claims 1 through 18, an intermediate portion connected to said terminal retention portion and being at least partly flexible, and a contact portion.

### BRIEF DESCRIPTION OF THE DRAWINGS

Other uses and advantages of the present invention will become apparent to those skilled in the art upon reference to the specification and the drawings, in which:

FIG. 1 shows a schematical cross section through a connector in which an example of one right-angle receptacle terminal in accordance with the present invention is applied;

FIGS. 2a and 2b, respectively, show cross sections through an empty cavity and a cavity with receptacle terminal, respectively, along line IIa-IIa and IIb-IIb, respectively, in FIG. 1;

FIGS. 3a and 3b,respectively, show cross sections through an empty cavity and a cavity with a receptacle terminal, respectively, along line IIa-IIa and IIIb-IIIb, respectively, in FIG. 1; FIGS. 4a and 4b, respectively, show cross sections through an empty cavity and a cavity with receptacle terminal, respectively, along line IVa-IVa and IVb-IVb, respectively, in FIG. 1; FIGS. 5a and 5b, respectively, show cross sections through an empty cavity and a cavity with a receptacle terminal, respectively, along line Va-Va and Vb-Vb, respectively, in FIG. 1;

FIGS. 6a and 6b, respectively, show cross sections through an empty cavity and a cavity with a receptacle terminal, respectively, along line VIa-VIa and VIb-VIb, respectively, in FIG. 1;

FIG. 7a shows a schematic cross section through a connector with five right-angle terminals in one column, the upper four terminals being provided with barbs in their retention portions and the terminals having twists both in the flexible hinge and within the tail portion;

FIG. 7b shows an enlarged view of section VIIb in FIG. 7a showing one of the barbs of a terminal;

FIGS. 8a, 8b, 8c, and 8d show different stages during the process of manufacturing receptacle terminals in accordance with the present invention;

FIGS. 9a through 9c show receptacle terminals intended for column insertion and having contact portions of different length for right-angle application;

FIGS. 10a, 10b, 10c, and 10d show different views of a straight connector in accordance with the present invention;

FIGS. 10e and 10f show different views of a straight connector in which some of the terminals are twisted through 45° ;

FIGS. 11a through 11i show different views of an alternative embodiment of the present invention in which the receptacle terminal is provided with a receptacle portion which is folded through 90° relative to the tail portion of the terminal;

FIG. 12 shows a further embodiment of the present invention, in which the contact portions of the terminals are designed for surface mount application;

FIGS. 13a through 13d show the application of the principles of the present invention to power contact terminals;

FIGS. 14a through 14g show the application of a strip of material to connect several connectors parallel to one another to form one monoblock of a desired length;

FIGS. 15a, 15b, and 15c show an alternative strip for connecting several connectors in parallel, the connectors being of a header type;

FIG. 16 shows a strip for connecting several right-angle connectors in parallel to form one monoblock, the connecting strip having at the same time the function of hold-down and grounding to a printed circuit board;

FIG. 17 shows the same connecting strip as in FIG. 16, however, applied to a header type connector;

FIGS. 18a-18e show further floating tuning fork terminals with alternative hinges;

FIG. 18f shows a cross section along line XVIIIf-XVIIIf in FIG. 18a;

FIGS. 19a through 19e show different views of connectors with floating pin terminals; and

FIG. 20 shows several connectors designed to cooperate with one another.

### DETAILED DESCRIPTION OF THE PREFERRED EMBODIMENTS

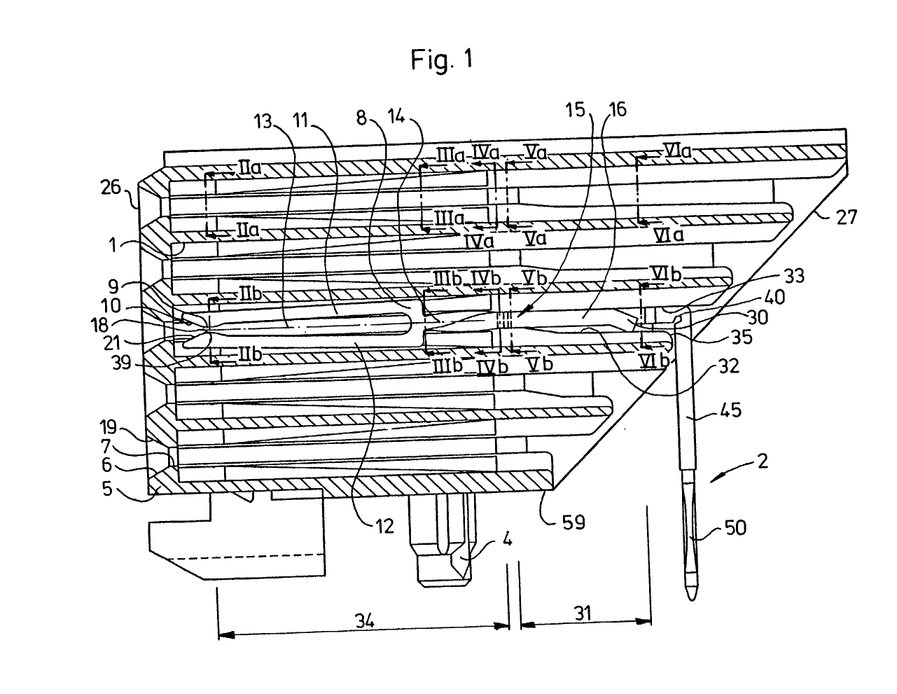

The connector, as shown in cross section in FIG. 1, comprises a connector housing 5 having a mating side 26 for mating contact with a header connector (not shown in FIG. 1), a mounting side 59 for mounting the connector to a printed circuit board or the like, and a rear side 27 being the side into which terminals may be inserted during assembly. The housing 5 is preferably a one-piece housing. The connector comprises a receptacle terminal 2 of a right-angle type. The receptacle terminal 2 is of the tuning fork type having two tines 11, 12. The two tines 11, 12 are provided with contact lead-in's 10, 21, and with contact domes 9, 39. Between the contact domes 9, 39 there is a contact gap 18 for receiving a pin terminal of a mating connector. The line 13 is the axis of symmetry of cavity 1.

The tines 11, 12 together form a tuning fork type receptacle portion 8 which is supported by a hinge 14. In the embodiment according to FIG. 1 the hinge 14 is shaped as a twist of 90° between the receptacle portion 8 and a tail portion 15. Thus the main side surfaces of the tines 11, 12 extend in a direction substantially perpendicular to the main side surface of the tail portion 15. Here, “main side surfaces” refer to those sides of the terminal portions which stem from the flat, rolled side surface of the basic stock material from which the terminal is stamped.

The twisted hinge 14 not only provides the desired 90° rotation of the receptacle portion 8 relative to the tail portion 15, but also a support of the terminal providing a flexible, floating capability of receptacle portion 8 within cavity 1, contained by connector housing 5 of the connector. The floating capacity of the receptacle portion 8 solves the problem of relative misalignment of a pin terminal (not shown) cooperating with the receptacle portion 8. In this condition, there is mutual misalignment between mating contacts, whereas the difference in normal force applied by each tine 11, 12 to a mating pin, is minimized.

It should be understood that without this flexible movement/adaptation possibility of the receptacle portion, there is an imbalance in the normal force support force exerted on either side of the pin contact faces, due to this misalignment. In a certain extreme case, the force acts on only one pin contact side. As is known to a person of skill, such force imbalance is contributory towards an overstress of the spring resulting ultimately in a poor electrical connection and a failure of the electrical connector.

Each cavity 1 is provided at the connector mating side with a trapezoidal lead-in 19 with one surface 6 merging into a rectangular pin guide hole 7. The axis of symmetry 13 is the ideal axis of insertion of a mating pin terminal.

Tail portion 15 is provided with a retention portion 16 fixedly accommodated over the a cavity retention portion 31. The length of this portion 31 varies for each row. The means of retention for the different rows are similar, although this is somewhat different for the lowest row. The portion of the cavity floatingly accommodating the receptacle portion 8 in this figure has been indicated by reference number 34.

The terminal retention portion 16 is, preferably, provided with at least one barb 30. At its upper side the terminal retention portion 16 rests against top wall 33 of the cavity 1, whereas barb 30 digs slightly into bottom wall 32 of cavity 1. The retention of the lowest row terminal is friction-fit.

The terminal 2 is provided with a nicking zone 40 in order to facilitate the forming of a right-angle tail portion of the connector. Towards this end, the terminal 2 is bent through 90° at the nicking zone 40. Such a nicking zone ensures a sharp perpendicular tail bend, which, in addition, results in an increased load bearing surface which will be beneficial during press-fit terminal insertion.

The nicking zone 40 provides the transition between tail portion 15 and a contact portion 45. The contact portion 45 is to establish an electrical contact to e.g. a printed circuit board (not shown in FIG. 1) or the like. However, the contact portion 45 may also be to provide a contact to a further connector or the like. As shown in FIG. 1, the contact portion 45 is provided with a press-fit section 50 for establishing a press-fit connection to a plated through-hole of a printed circuit board.

The housing 5 of the connector is provided with a plastic peg 4 integral with the housing 5 which can be inserted into a mating hole of a printed circuit board to facilitate the connection of the connector to the printed circuit board.

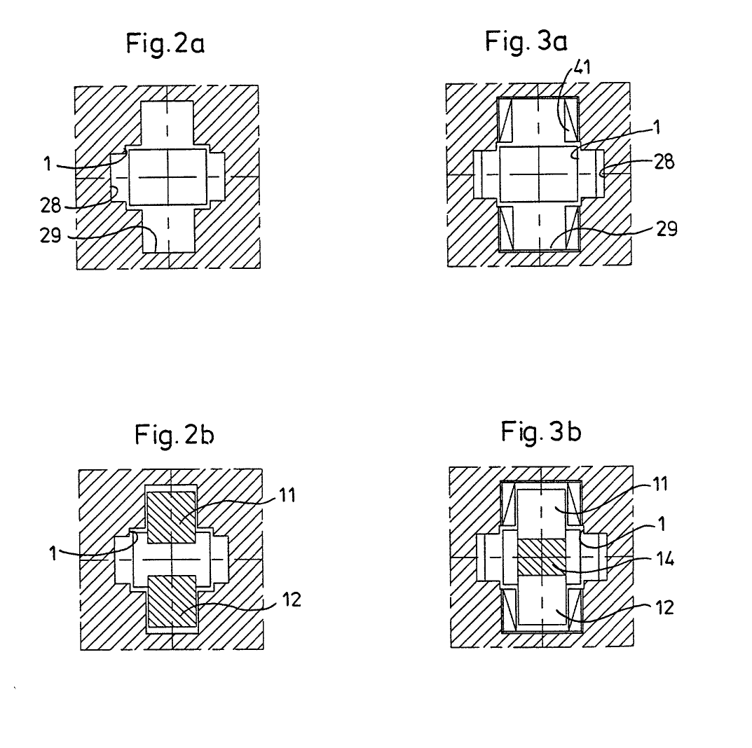

FIGS. 2a through 6b show details of the present connector in cross sections along lines IIa-IIa through VIb-VIb in FIG. 1.

FIG. 2a shows one cavity in cross section along line Ia-Ia in FIG. 1. At line IIa-IIa the cavity 1 has a cross-shaped cross section. The cavity 1 is provided with a first slit-shaped opening 28 extending in a first plane. Moreover, the cross section shows that the cavity 1 is provided with a second slit-shaped opening 29 extending in a second plane substantially perpendicular to the first plane.

FIG. 2b shows the cavity 1 with a cross section of the two tines 11, 12 along line IIb-IIb. As is evident from FIG. 2b, the tines 11, 12 are floating within cavity 1.

FIG. 3a shows a cross section of cavity 1 along line IIIa-IIIa. As can be seen from FIG. 3a the cross section along line IIIa-IIIa is largely identical to the cross section of FIG. 2a along line IIa-IIa. Only the height of the slit-shaped opening 29 is larger at line IIIa-IIIa than at line IIa-IIa, and the width of the slit-shaped opening 28 is larger at line IIIa-IIIa than at line IIa-IIa. Between line IIIa-IIIa and line IIa-IIa the slit-shaped opening 29 is provided with a slightly inclined surface 41, at a limited location in area 34 (see FIG. 1), to facilitate the insertion of the tines 11, 12 during assembly.

FIG. 3b shows a cross section through cavity 1 and the terminal at line IIIb-IIIb. From FIG. 3b one can easily deduce that at line IIIb-IIIb the hinge 14, which is supporting the receptacle portion 8 of the terminal 2, is also floating within cavity 1.

FIG. 4a shows a cross section through cavity 1 along line IVa-IVa. This cross section is identical to the cross section of cavity 1 as shown in FIG. 3a.

FIG. 4b shows a cross section through cavity 1 with terminal 2 along line IVb-IVb. At IVb-IVb the floating hinge 14 starts and is connected to the tail portion 15.

FIG. 5a shows a cross section through cavity 1 along line Va-Va just behind the cross section shown in FIG. 4a. The cross section according to FIG. 5a does not essentially differ from the cross section shown in FIG. 4a. Slit-shaped opening 28 is shown to have a top wall 33 (see FIG. 1) and a bottom wall 32.

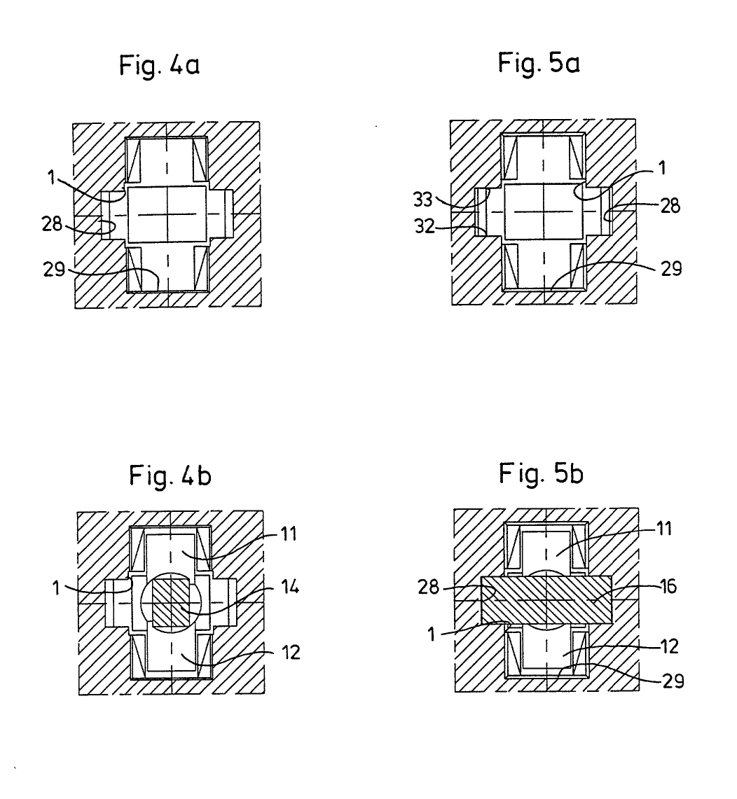

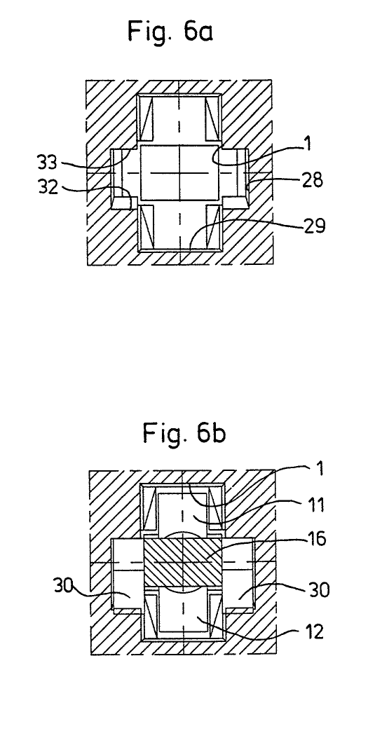

FIG. 5b shows a cross section through cavity 1 and terminal 2 along line Vb-Vb. As one can clearly see from FIG. 5b the terminal 2 is provided with a retention portion 16 which is fixedly accommodated within the slit-shaped opening 28, whereas the slit-shaped opening 29 is dimensioned large enough to let the receptacle portion 8 with tines 11, 12 pass, freely, during assembly. FIG. 6a shows a cross section through cavity 1 along line VIa-VIa in FIG. 1, slightly behind barbs 30. From FIG. 6a one can deduce that the bottom wall 32 of the slit-shaped opening 28 is inclined relative to the axis of symmetry 13 of cavity 1 such that the height of slit-shaped opening 28 is reduced inwardly.

FIG. 6b shows the cross section of cavity 1 and the cross section of the terminal 2 along line VIb-VIb. In FIG. 6b one can clearly see the application of two barbs 30, which are fixed to the retention portion 16 and which are stiff and sharp in order to cut into the plastic housing wall 32 whenever the terminal 2 is stitched into cavity 1 during assembly. The retention portion 16 is pushed firmly against top wall 33 by the barbs 30 during assembly. By doing so, not only a terminal retention in the housing 5 is achieved, but also the receptacle terminal 2 is optimally centred and symmetrically located along the axis of symmetry 13 of cavity 1. Hence, top wall 33 is a reference surface for terminal location in the connector housing after assembly.

The mutual interface of top wall 33 and the rear side of the retention portion abutting top wall 33, form a common reference plane for each row of contacts. Note, that it is this mutual interface between the retention portion 16 and the top wall 33 which may later be utilized in right-angle applications as load bearing area to push the press-fit section 50 into a plated through-hole of a printed circuit board. To achieve said press-fit connector application, the top surface of the receptacle connector housing 5 is used as an anvil whereby each cavity top wall 33 exerts the relatively high force of pin insertion.

As is observed in FIGS. 1 through 6b, the tuning fork portion 8 is shown to be rotated through 90° relative to the tail portion 15. However, the angle of rotation may vary as desired.

Preferably, two barbs 30 are applied at opposing sides of retention portion 16. However, the number of barbs 30 may be less or more. Also no barb at all may be present. This is particularly so for the lowest row terminal; this can be force fit in a tapering cavity in housing 5.

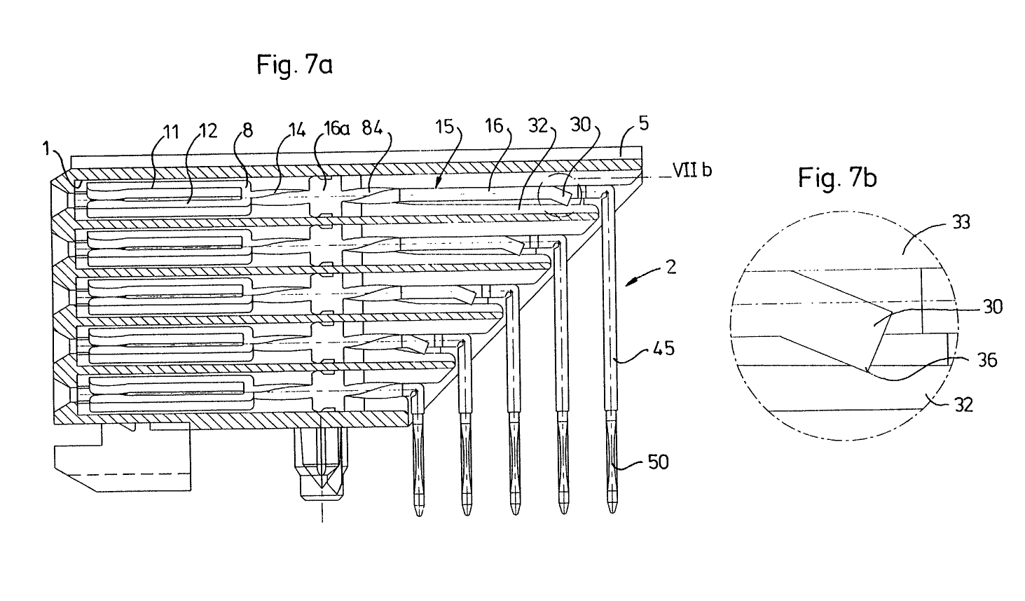

FIG. 7a shows a cross section through a receptacle connector according to the invention having five receptacle terminals 2 mounted in any of its columns. The same reference numbers as in FIG. 1 refer to the same elements or constructive details. The explanation will not be repeated here. One purpose of FIG. 7a is to show that the barbs 30 of adjacent receptacle terminals within one and the same column of contacts are both horizontally and vertically offset with respect to one another. Thus, although the barbs 30 cut into the bottom walls 32 of the cavities, as is further shown in detail in FIG. 7b, any plastic deformation of the connector housing 5 (and hence retention force) due to this offset of the barb 30, do not have the reactionary forces of different rows within one column of contacts cumulatively interacting along one line, but are displaced horizontally to each other. Any plastic deformation due to the barbs 30 will occur in a position offset in adjacent cavities in any single column. This feature is important to avoid local stress concentration in the housing within the assembled connector.

Another purpose of FIG. 7a is to show that the angle of twist in flexible hinge 14 might be 45° instead of 90°. Although not shown, any other desired angle may be applied. Moreover, the terminal 2 may be designed such that there is also a twist 84 of 90° within the retention portion 16. To this end, retention portion 16 may comprise the barbs 30, as explained before, and separate retention means 16a between hinge 14 and twist 84, securely accommodated by cavity 1. This latter twist may also include another angle than 90°. Although twist 84 is shown between flexible hinge 14 and barbs 30, twist 84 may be applied at the rear side of barbs 30, or even within contact portion 45.

FIG. 7a shows a right-angle connector. When the thickness of the terminal material is large enough, typically of the order of 0.5 mm, no press-block is necessary to manage the true-position of the contact ends belonging to the contact portions 45 prior to mass-inserting them into corresponding plated through-holes of a printed circuit board.

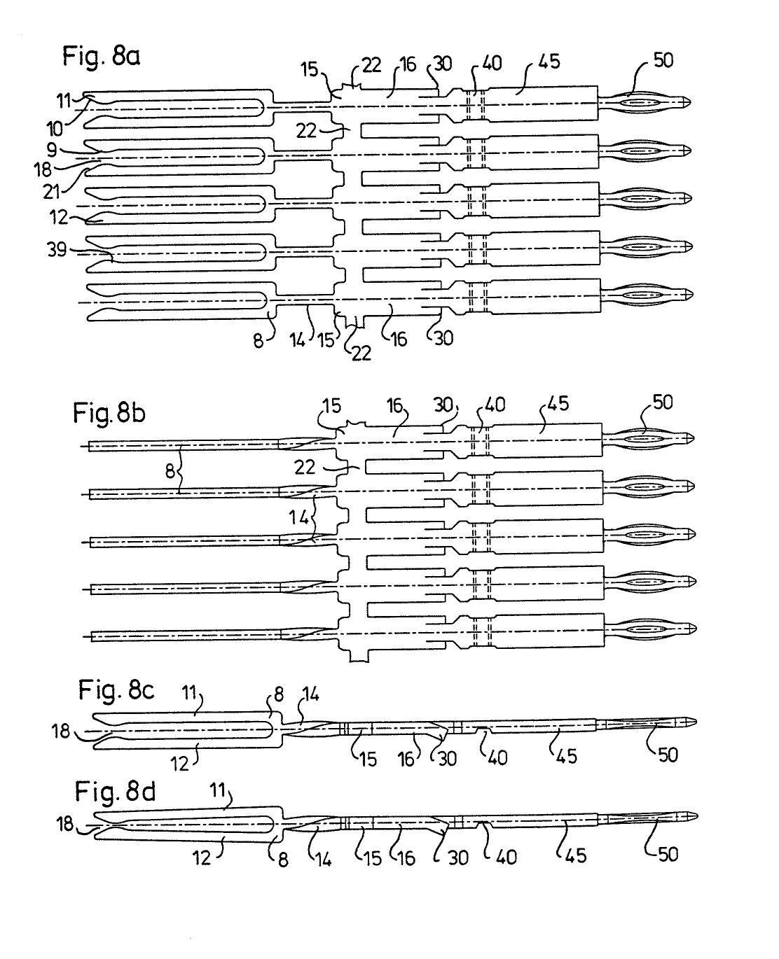

FIGS. 8a through 8d are made to show different process steps of producing a receptacle terminal. In FIG. 8a the initial stamp and plating step for the middle row (row “C”) of the final assembled connector is shown. The pitch of contacts in the terminal carrier is identical to the connector cavity pitch to permit future mass-insertion in the housing cavities. During this step the contact gap 18 is relatively large and the tines 11, 12 are parallel to each other. The hinge 14 is still in its normal, i.e. untwisted, flat stamp condition.

During this process stage the contact domes 9, 39 of the tines 11, 12 as well as the contact lead-ins 10, 21 may be smoothened in accordance with the method disclosed in European patent application 95203317.3, filed by the proprietor of the present invention. The tail portion 15 is provided with a retention portion 16 which has two barbs 30 formed by shearing the material in a manufacturing die. The tail portion 15 is connected to the contact portion 45 which ends in a press-fit section 50. Nicking zone 40 between the tail portion 15 and the contact portion 45 has been indicated with two parallel dashed lines. Adjacent terminals are connected to one another by means of connecting shoulders 22 in the terminal carrier. FIG. 8b shows several receptacle terminals still connected with connecting shoulders 22 but after twisting the hinge 14 such that the main side surfaces of the tuning fork receptacle portions 8 are rotated through 90° relative to the tail portion 15.

FIG. 8c shows a side view of the receptacle terminals of FIG. 8b. As one can clearly see the barbs 30 are bent somewhat to extend from the plane defined by the tail portion 15. After mass-stamping out the connecting shoulders 22 between adjacent receptacle terminals the contact gap 18 of any of the receptacle terminals is given a predetermined size, as shown in FIG. 8d.

The plated strip as shown in FIGS. 8a and 8b is held in an assembly machine. After mass-stamping out the connecting solders 22 the loose piece terminals are located on a stitch slide (not shown). This stitch slide then mass-inserts all terminals belonging to one row into one row of cavities 1 of the housing 5 for the desired stitch depth, and then the stitch slide is retracted to its initial location for a new cycle. As mentioned above, after insertion of a row of terminals the straight rear leg portion of the row of these terminals can be bent at the nicking zone 40 to achieve a right-angle product.

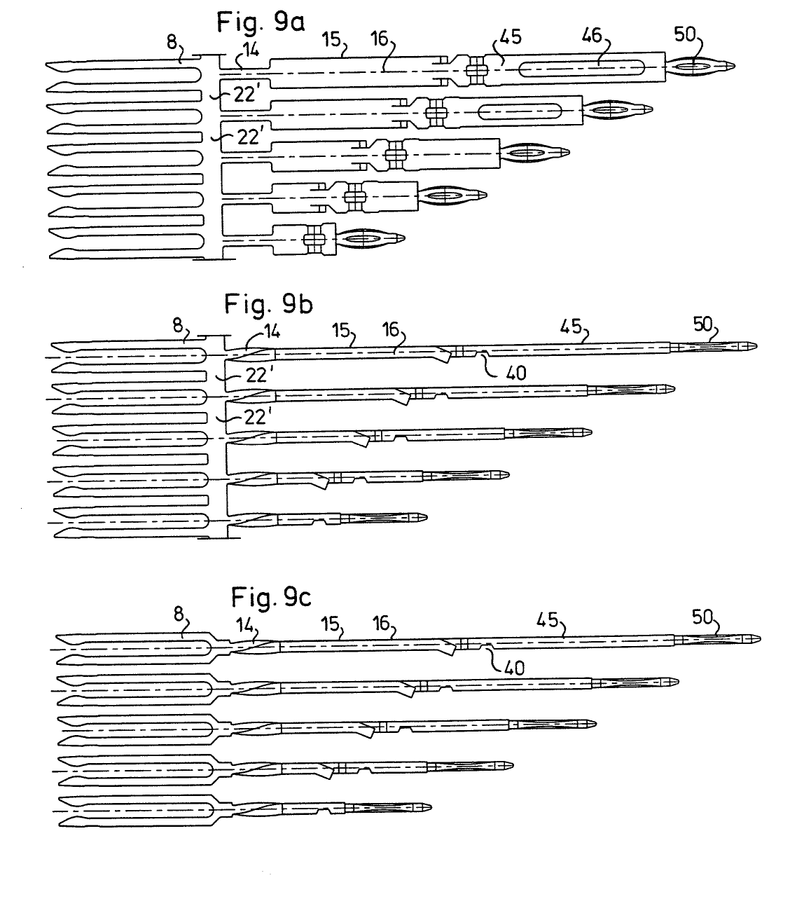

In the foregoing discussion a right-angle connector has been discussed, which may be utilized for mass-insertion by rows. Now, right-angle connectors for mass-insertion by columns will be discussed. Another option is to have all the right-angle terminals stamped out directly as a lead frame. However, as a result of this decision, there needs to be a minimum spacing between terminals on a carrier for adjacent columns. This would result in a higher material usage than if all the tail portions are initially straight after stamping as shown in FIG. 9a; also the concept of FIG. 9a allows easy adaptation of the tail length (as may be required to permit rear plug-up or wire-wrap as will be discussed in the forthcoming discussion).

FIG. 9a shows initial stamp and plated receptacle terminals located adjacent to each other for five connector rows (i.e. for five cavities within one single column). During stamping the five receptacle terminals are connected to each other by connecting shoulders 22′. It is to be noted that the locations of the connecting shoulders 22′ differ compared to the locations of the connecting shoulders 22 in the embodiment according to FIGS. 8a and 8b. The reason is that the terminals shown in FIG. 9a through 9c are intended for column insertion which necessitates the rotation of tail portions 15 relative to the respective tuning fork portions 8 prior to inserting the terminals into corresponding cavities of the connector.

The terminals are positioned on the stamp carrier adjacent to each other with a pitch which is equivalent to that between the adjacent cavities of one row of the housing used in assembly. Hence, there is reduced material usage and easier adaptation of the tail length of the different terminals. This is, contrary to the so-called lead frame concept, straight after stamping. After the terminals have been inserted into the housing, the tails are bent through 90°.

FIG. 9b shows that the tail portions 15 are twisted whereas the tuning fork portion orientations remains unchanged. FIG. 9c shows the five terminals after stamping out the connecting shoulders 22′.

The terminal contact shank 45 for the upper row terminals may have impressed regions 46 to stiffen their extended length, as shown in the upper two terminals in FIG. 9a, but not shown in FIGS. 9b and 9c. The purpose of this additional stiffness is to overcome (axial) column buckling tendency encountered during press-fit application of the right-angle connector contact portions into the holes of a printed circuit board. For the lower rows with shorter contact shanks 45, the buckling force is not predominant and in such cases there is no requirement to have impressed regions 46. Hence, such impressed regions 46 can be introduced selectively as a part of the stamping process.

So far, the discussion concerned primarily the right-angle or horizontal mating connector. Below ensues a discussion for details concerning the straight or vertically stacking connector in accordance with the present invention.

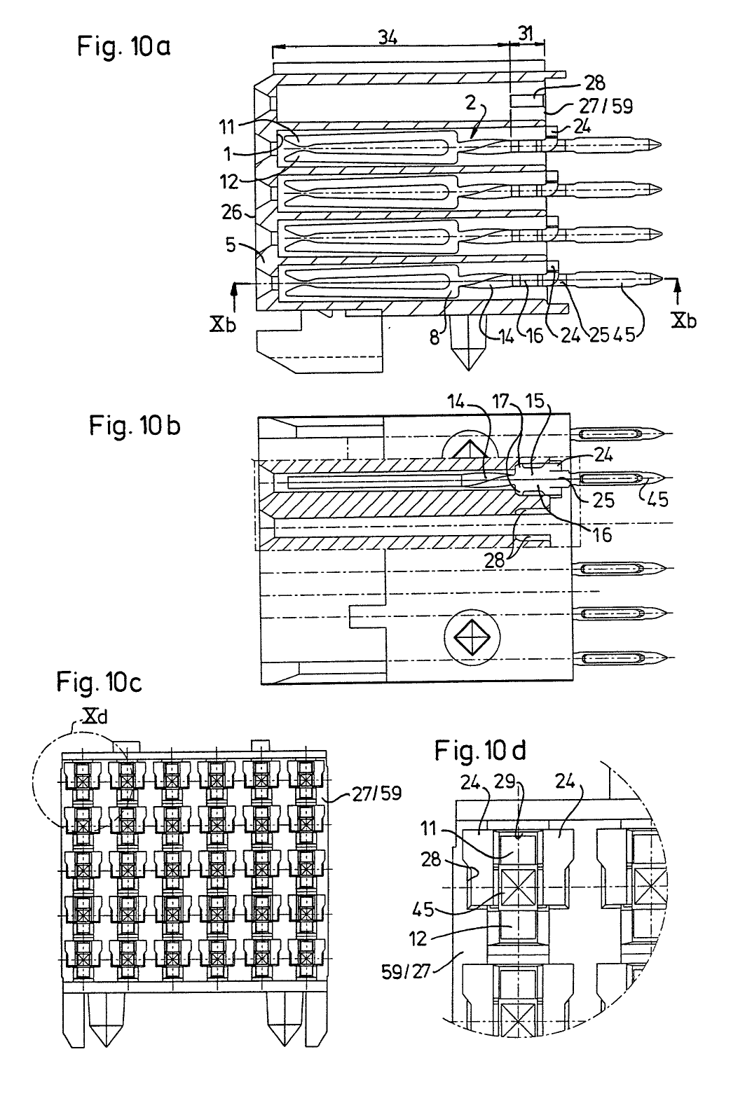

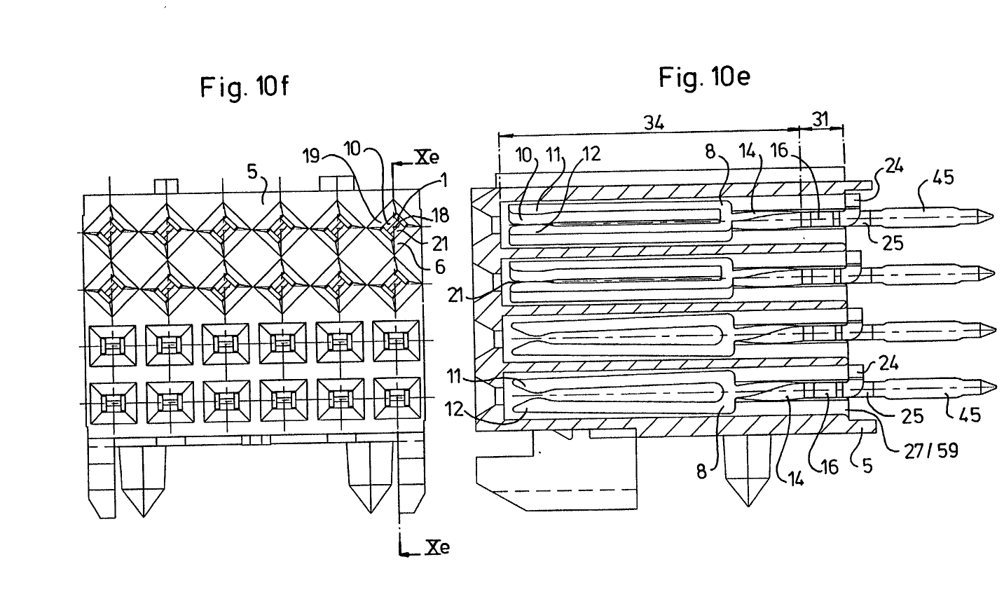

FIGS. 10a through 10d show different views of a straight-angle connector. FIG. 10a shows a cross section through such a connector along one of its columns. Analogous to FIG. 1, the receptacle portion 8 with the twisted hinge 14 is floating within the front portion 34 of the cavity 1, whereas the retention portion 16 is fixedly accommodated within retention portion 31 of the cavity 1.

In this case the mounting side 59 of the connector, i.e. the side of the connector intended to be mounted to a printed circuit board or the like, is substantially parallel to the mating side 26 of the connector intended, i.e. the side of the connector intended to cooperate with a mating connector. In other words, in the embodiment according to FIGS. 10a-10d, the mounting side 59 and rear side 27 coincide. Therefore, there is less space available within the connector housing 5 for the retention of the receptacle terminals 2. Still, the retention portion 31 of the cavity 1 has two slit-shaped openings 28, 29 as in the right-angle embodiment. The slit-shaped opening 29 is large enough for passing the receptacle portion 8 during insertion of the receptacle terminal into cavity 1. The other slit-shaped opening 28 is small enough to accommodate the retention portion 16 of the terminal 2 in a fixedly manner.

In order to provide an even firmer grip, the retention portion 16 may be provided with barbs 17, as shown in FIG. 10b. FIG. 10b is a cross section through the cavity of the connector of FIG. 10a along line Xb-Xb, and shows a bottom view of terminal 2 as observed from the rear side of a straight connector.

The receptacle terminal 2 is provided with at least one lobe 24 extending substantially perpendicular to the plane defined by the retention portion 16. After inserting the receptacle terminal 2 into the housing 5 the lobe 24 abuts the mounting side 59 of the connector housing 5. First of all, this gives a proper definition of the depth of insert of the individual terminals 2. Moreover, these lobes 24 avoid any shift of the receptacle terminals 2 whenever the contact portions 45 of this straight connector are inserted into the plated through-holes of a printed circuit board (not shown).

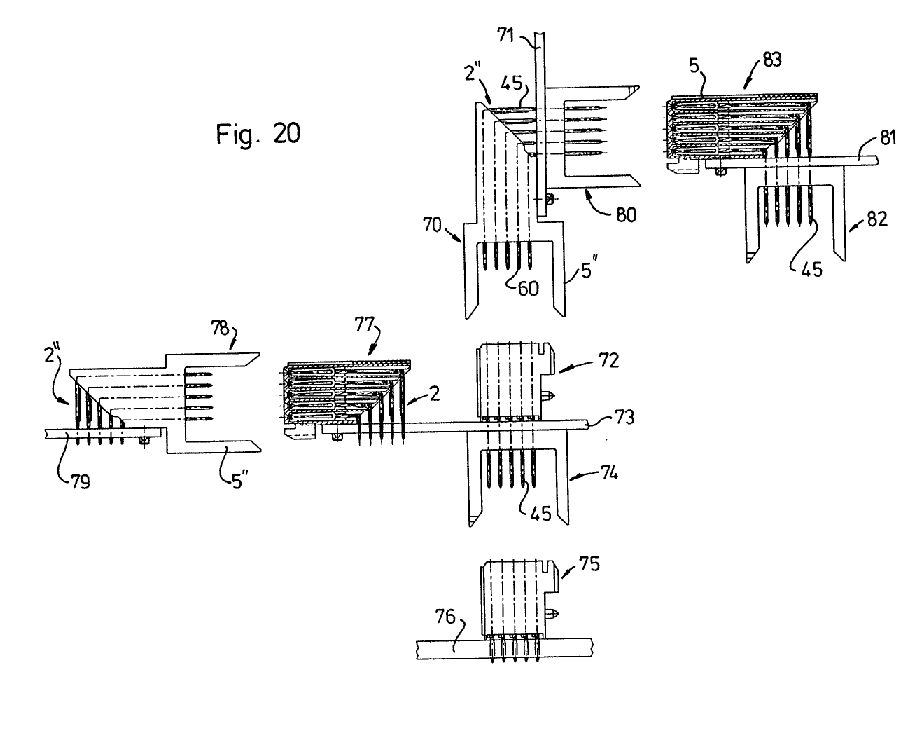

Although the contact portions 45 have been shown to be H-shaped press-fit contacts (see FIG. 10b) any other desired press-fit shape or desired type of contact may be applied. The contact portion may e.g. be an eye-of-needle press-fit contact, a wire-wrap contact, a male contact, a hold down contact, or any arbitrary solder contact. Even a contact portion with extended length may be envisaged, wherein the contact portion comprises a first contact portion, e.g. a press-fit contact, and a second portion extending from the first portion, e.g. a pin contact. As will be explained below with reference to FIG. 20, after inserting such a contact portion with its press-fit section fitting into a printed circuit board hole, the second contact portion extending from the printed circuit board may be for instance used for further connection to a receptacle connector.

FIG. 10c shows a rear view of the connector of FIG. 10a. The connector is shown to have five rows and six columns, however, this is by way of example only. FIG. 10d shows an enlarged view of a detail of FIG. 10c, i.e. of the section Xd in FIG. 10c. In FIG. 10d one can clearly see the upstanding lobes 24 abutting the mounting side 59 of the connector. Moreover, the same reference numbers refer to the same elements as in the former FIGS. Their explanation will not be repeated here. FIG. 10d shows that the terminals are provided with two lobes 24 which are both folded in the same, upward direction. However, they may alternatively be both folded downward. As a further alternative, they may be folded in opposing directions.

FIG. 10e shows a further connector in accordance with the present invention. In the connector according to FIG. 10e, the terminals of the upper two rows are bent through 45° instead of through 90°. FIG. 10f shows a front view of the same connector, whereas FIG. 10e shows a cross section along line Xe-Xe in FIG. 10f. The same reference numbers in FIGS. 10e and 10f refer to the same elements and components as in the former FIGS. The terminals of the top two rows in FIGS. 10e and 10f may be equal to those shown in FIG. 10b, the only difference being that the hinge 14 comprises a rotation through 45° instead of 90°. In the embodiments according to FIGS. 10e and 10f, the first opening 29 (not shown) and the second opening 28 (not shown) of the retention portion 31 of the cavity 1 are in different planes having an angle of intersection of 45°.

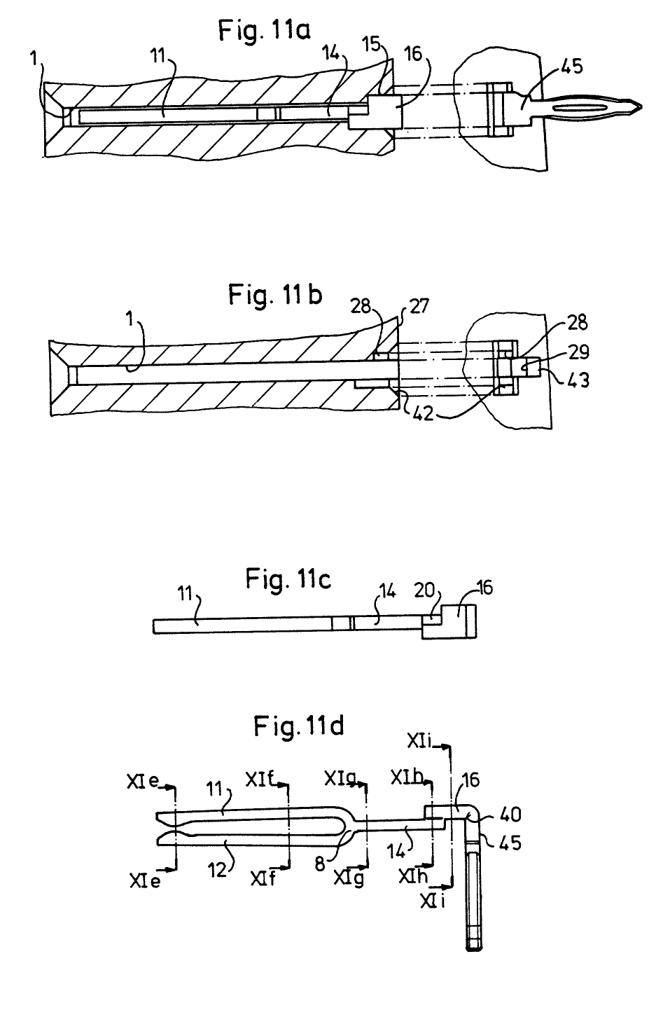

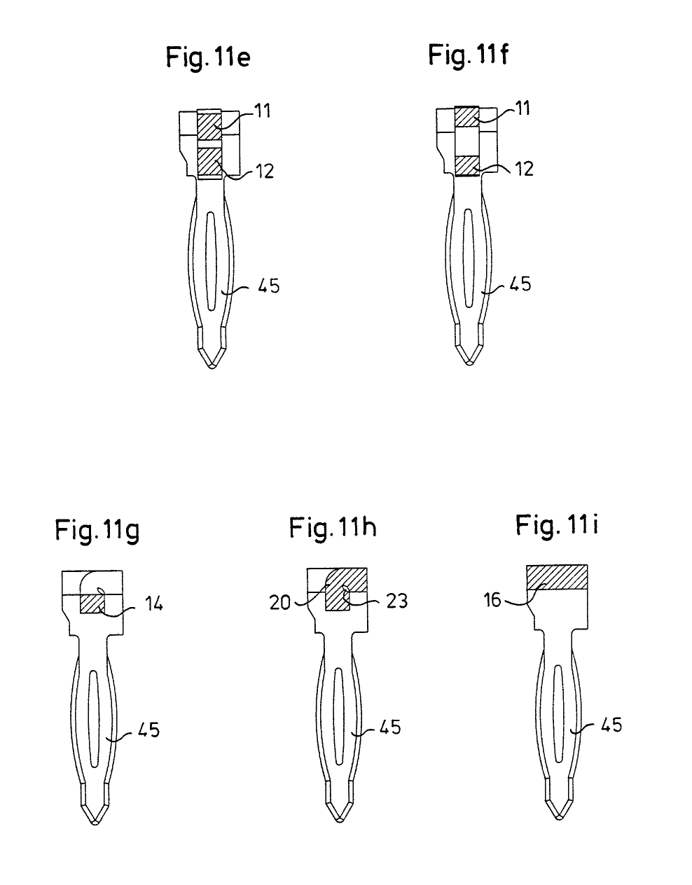

FIGS. 11a through 11i show a further alternative embodiment of a receptacle terminal in accordance with the present invention. The same reference numbers refer to the same elements as in the former FIGS. and their explanation will not be repeated.

The main difference between the receptacle terminal of FIGS. 11a through 11i and the former FIGS. is that the hinge 14 is not a twisted section. Instead, the intermediate portion of the receptacle terminal between the receptacle portion 8 and the retention portion 16 is provided with both a flexible floating hinge 14 and a fold section 20.

FIG. 11a shows a cavity 1 with the alternative embodiment of the receptacle terminal. In the right-hand portion of FIG. 11b a rear view of the left-hand portion of FIG. 11a is given.

FIG. 11b shows the cavity 1 without the receptacle terminal. In the right-hand portion of FIG. 11b a rear view of the left-hand portion of FIG. 11b is given. From FIG. 11b it is evident that the cavity 1 is, again, provided with two slit-shaped openings 28, 29. Whereas the slit-shaped openings 28 and 29 in the former embodiments more or less formed a cross, in the embodiment according to FIGS. 11a through 11i the slit-shaped openings 28 and 29 now form a “T”. In order to facilitate the insertion of a terminal into cavity 1, the slit-shaped openings 28, 29 are provided with bevelled edges 42 and 43, respectively, at the rear side 27 of the connector.

FIG. 11c shows a top view of one of the receptacle terminals having a floating, flexible hinge 14 and a fold section 20.

FIG. 11d shows a side view of the receptacle terminal shown in FIG. 11c. In FIG. 11d one can clearly see that the receptacle portion 8 is rotated through 90° relative to the retention portion 16 by folding fold section 20 through 90°.

Although the retention portion 16 is not shown to have any barbs, of course, barbs like 30 or 17 may be applied in the embodiment according to FIGS. 11a through 11i.

FIGS. 11e through 11i show cross sections through the receptacle terminal along lines XIe-XIe, XIf-XIf, XIg-XIg, XIh-XIh, and XIi-XIi, respectively, indicated in FIG. 11d.

It is observed, that in FIGS. 11a through 11i the tuning fork portion 8 is shown to be rotated through 90° relative to the tail portion 15. However, the angle of rotation may vary as desired.

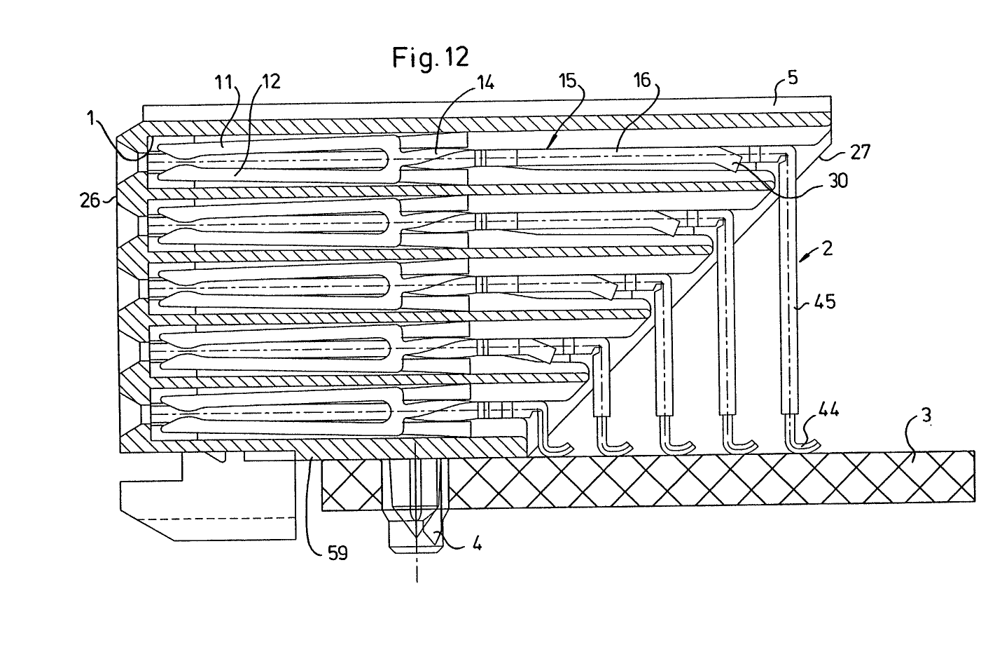

FIG. 12 shows an embodiment of the invention in which the contact portions 45 are provided with spoon-like contacts 44 for surface mounting the connector to a printed circuit board 3. The technology of surface mounting is known to persons skilled in the art and does not need any further explanation. The same reference numbers in FIG. 12 refer to the same elements as in FIG. 1. As is evident from this FIG., there is now no impediment for reflow energy to undertake the desired solder reflow operation. Neither are there any problems associated to “joint” inspection after reflow.

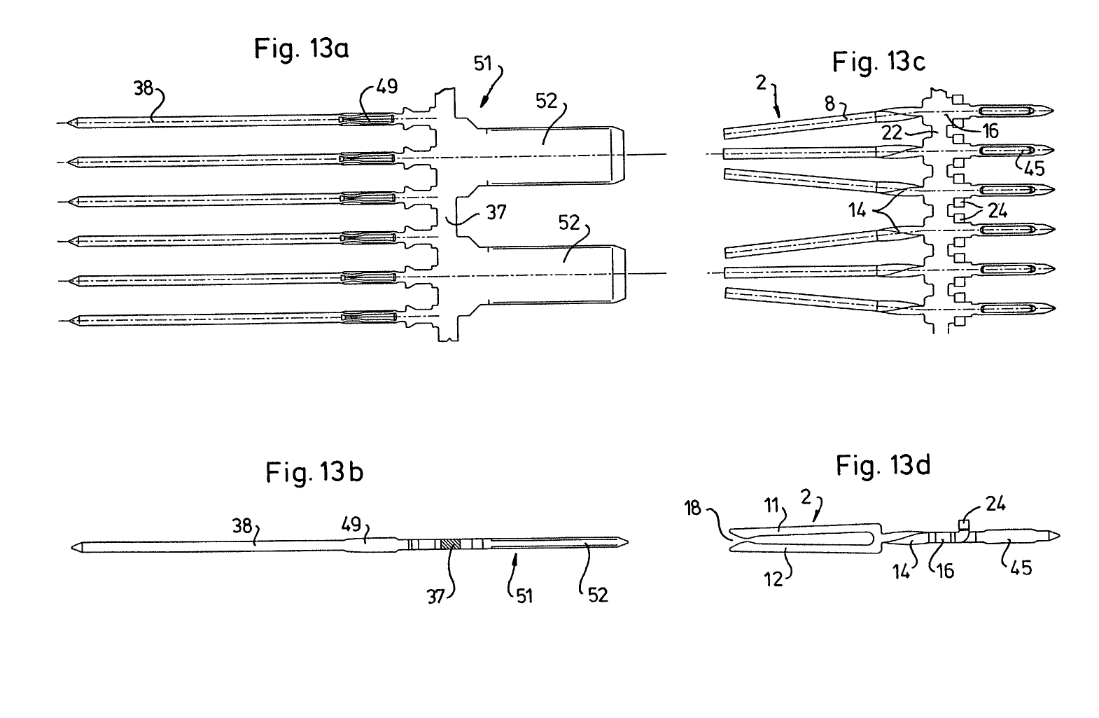

FIGS. 13a through 13d show the application of the present invention to power contacts. The objective is to increase the mating contact cross-sectional area of the plug and receptacle contacting portions which cumulatively contribute to the flow of (relatively high) electrical power energy, without unduly local overheating of the connector. In FIG. 13a two power terminals 51 are shown which are still interconnected by means of a connecting shoulder 37. During assembly the connecting shoulder 37 will be stamped-out. Each of the power terminals 51 is provided with three tail portions comprising a wire-wrap contact 38 and a press-fit section 49, as shown in FIG. 13a. Each of the power terminals 51 is provided with a power contact 52 with relatively large dimensions. Also, each of the power contacts 52 obtains electrical current from three tail portions 38, 49.

FIG. 13b shows a side view of the power terminal 51 of FIG. 13a.

FIG. 13c shows a top view of a group of several receptacle terminals 2 which are still connected together by means of connecting shoulders 22. The receptacle terminals 2 are grouped together in sets of three receptacle terminals to constitute one receptacle power contact. The middle receptacle terminal of each of the groups is like the receptacle terminals from the former FIGS. In FIG. 13c the receptacle terminals are shown to be the receptacle terminals of FIGS. 10a through 10d. However, they can be replaced by any of the other embodiments shown in the former figures. Both outside receptacle terminals 2 of each of the groups are bent towards the middle receptacle terminal as shown in FIG. 13c such that the three contact gaps 18 of the three adjacent receptacle terminals 2 are so close to one another that they can together receive one power contact 52. Thus, the power available from one power contact 52 can be divided over three different receptacle terminals 2.

FIG. 13d shows a side view of one of the receptacle terminals 2 of FIG. 13c.

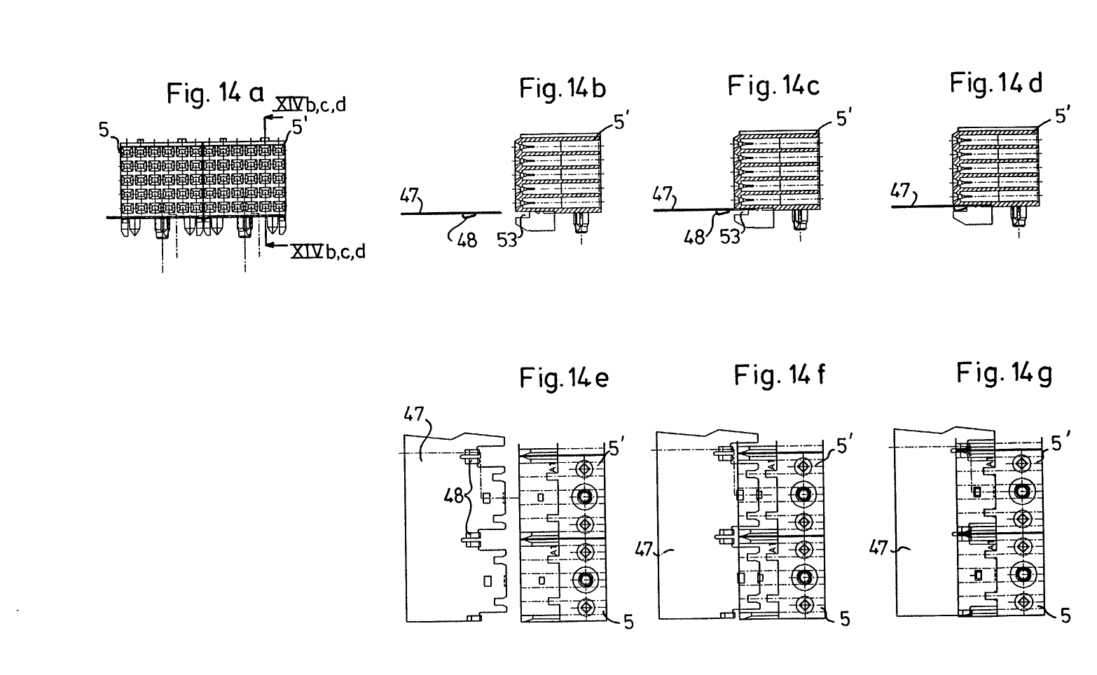

An entire connector, called Monoblock, may be built up of several separate, end-to-end stackable connector housings. FIG. 14a shows two parallel connector housings 5 and 5′, thus forming a connector with twelve columns and five rows. At this moment, the maximum connector size is 21 of such parallel connector housings. However, in future this could be more. In order to have flexibility and freedom in future requirements it is proposed to connect several connector housings together by means of a single strip 47. FIG. 14e shows a top view of such a strip 47. In the embodiment according to FIGS. 14a through 14h, the strip 47 is made of flexible metal.

FIGS. 14b, 14c, and 14d, respectively, show cross section views along line XIVb,c,d-XIVb,c,d in FIG. 14a during different stages of connecting several connector housings together by means of the strip 47. In FIG. 14b the strip 47 is in front of the parallel arranged connector housings. The strip 47 is provided with several lips 48 (see also FIG. 14e) which are able to cooperate with suitable openings 53 in the connector housing. FIG. 14c shows the strip 47 partly inserted into suitable openings 53 of the connector housing 5′, whereas FIG. 14d shows the strip 47 entirely inserted into the suitable openings 53 of the connector housing 5′, and thus connecting several parallel connector housings 5, 5′ together.

FIGS. 14e, 14f, and 14g, respectively, show bottom views of FIGS. 14b, 14c, and 14d, respectively.

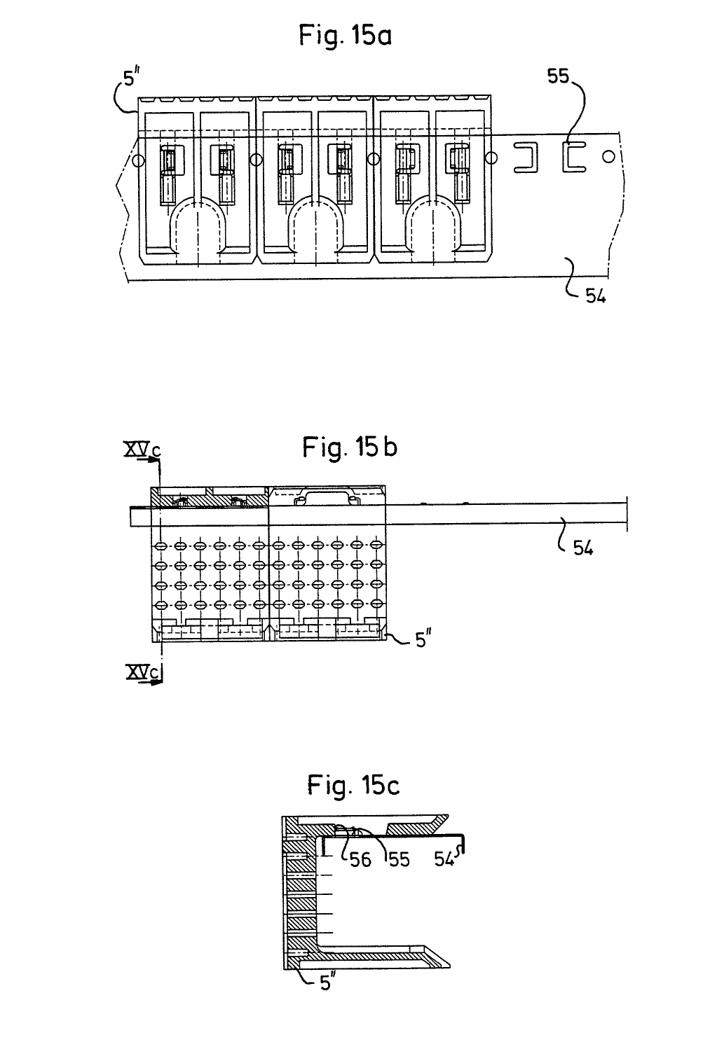

FIGS. 15a through 15c show the application of a strip 54 provided with extensions 55 cooperating with suitable openings 56 in the plastic housing 5′ of a header connector. FIG. 15a shows a top view of several header connectors connected together by the strip 54. FIG. 15b shows a front view, whereas FIG. 15c shows a cross section front view along line XVc-XVc in FIG. 15b. Both the strip 47 of FIGS. 14a through 14g and the strip 54 of FIGS. 15a through 15c may be made of metal. However, alternatively they may be made from a suitable plastic, metallized if desired.

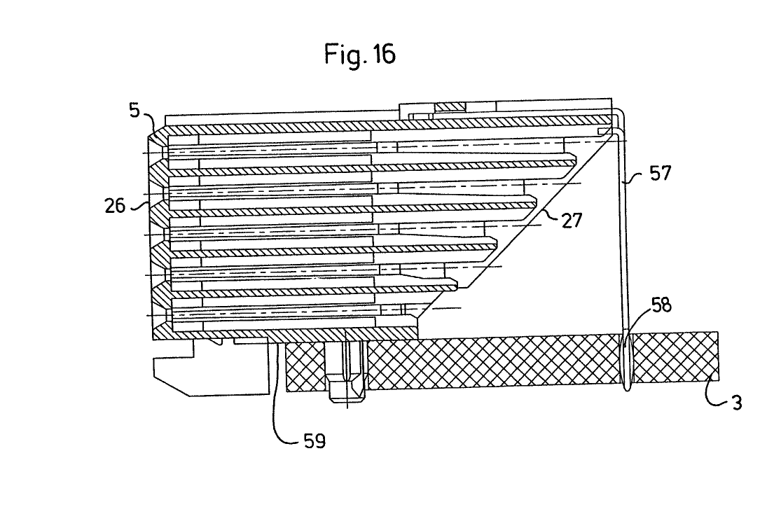

FIG. 16 shows an alternative strip 57 which is provided with suitable extensions to allow gripping of the top wall of the connector housing 5. The strip 57 extends along a predetermined length in order to allow gripping of several parallel arranged connector housings, as in FIGS. 14a through 14g, and FIGS. 15a through 15c. The strip 57 is shown to be provided with a press-fit contact 58 inserted into a plated through-hole of printed circuit board 3. When the outside wall of the connector housing 5 is metallized and the press-fit contact 58 is connected to an earthline (i.e. ground) on the printed circuit board 3, the housing 5 of the connector is grounded and forms a cage of Faraday for the terminals (not shown) within the connector housing 5.

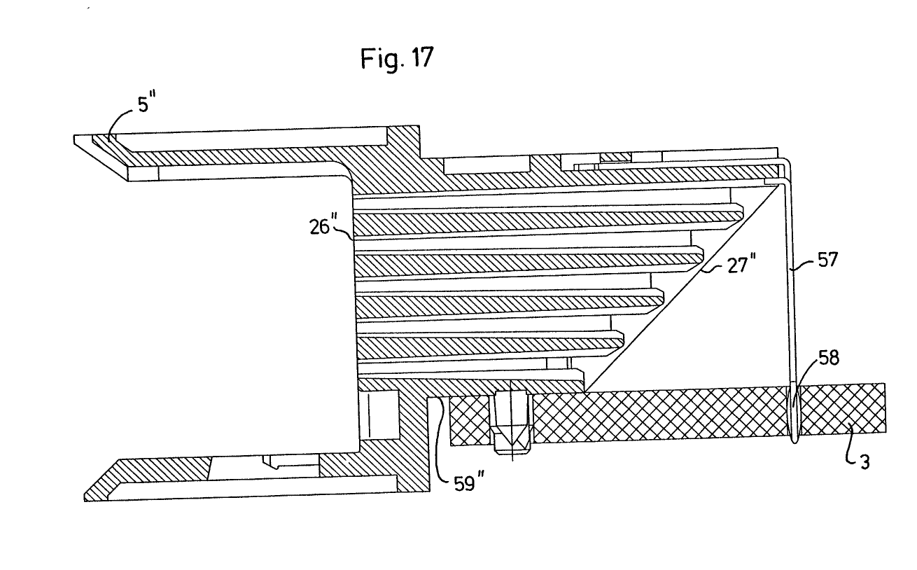

FIG. 17 shows that the strip 57 can also be applied to the housing 5″ of a right-angle, horizontal connector.

FIGS. 14a through 17 show that it is possible to connect several parallel arranged connector housings together by means of a strip. Thus a “monoblock” connector can be provided of any desired length. When, for some applications, the “monoblock” length is too large, a desired number of connector housings can just be removed by cutting off an appropriate length of the strip.

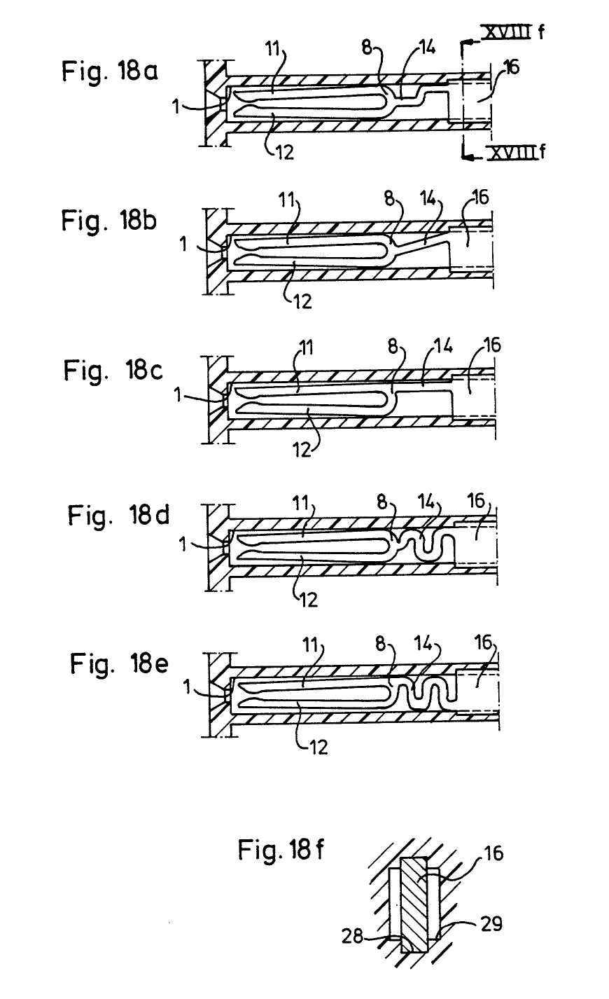

FIGS. 18a through 18e show alternative flexible hinges using the tuning fork receptacle contact as an example. All hinge designs are designated with reference number 14 and all allow the tuning fork portion 8 to float within cavity 1. At the same time, FIGS. 18a through 18e show that the tuning fork tines 11, 12 may be within the same plane as the retention portion 16. Then, the retention portion of the cavity 1 may have a cross section as shown in FIG. 18f. The retention portion of the cavity shown in FIG. 18f has a first opening 29 large enough to freely pass the tines 11, 12 during inserting the terminal into cavity 1, and a second opening 28 which has a larger height but a smaller width than opening 29 in order to securely accommodate retention portion 16. If desired, the height and/or the width of opening 28 may become smaller towards the mating side of the connector in order to render a firmer clamping when inserting the terminal deeper into cavity 1. Moreover, opening 28 may end at the transition between the front portion 34 and retention portion 31 of cavity 1 by means of an end wall 85, which, then, takes over the function of lobe 24 (FIG. 10a).

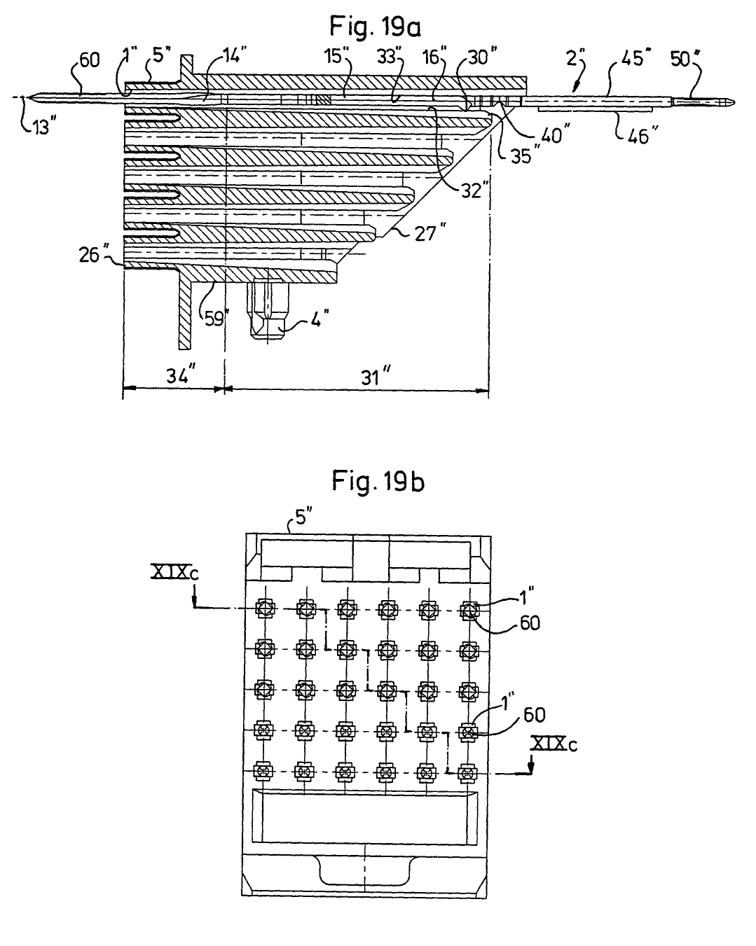

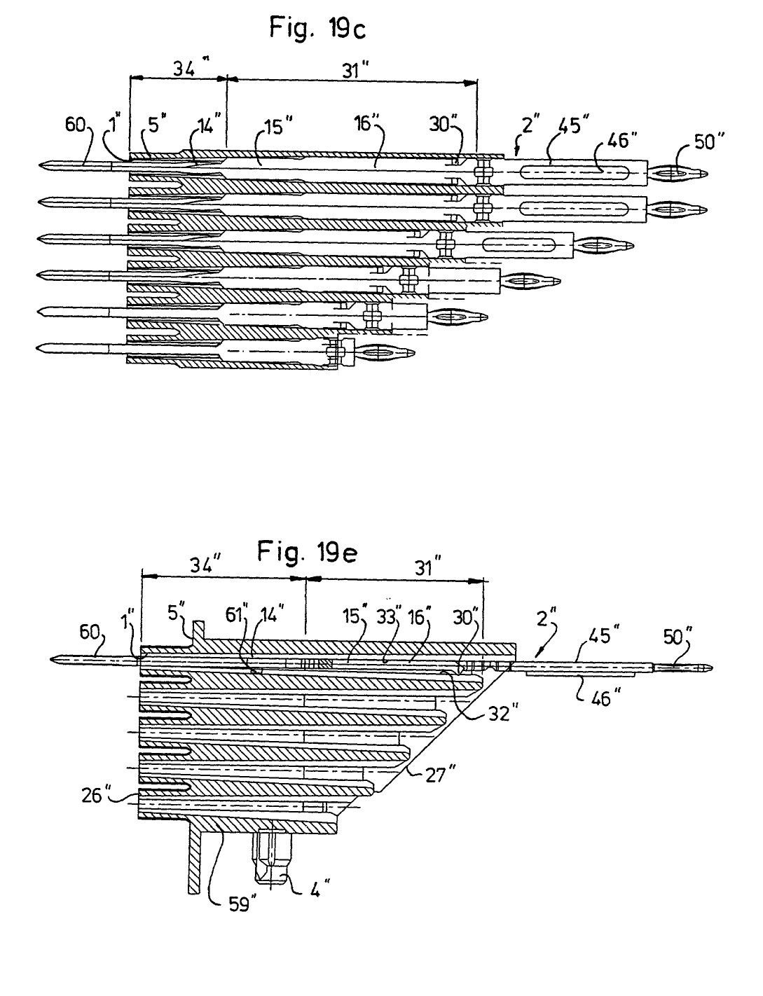

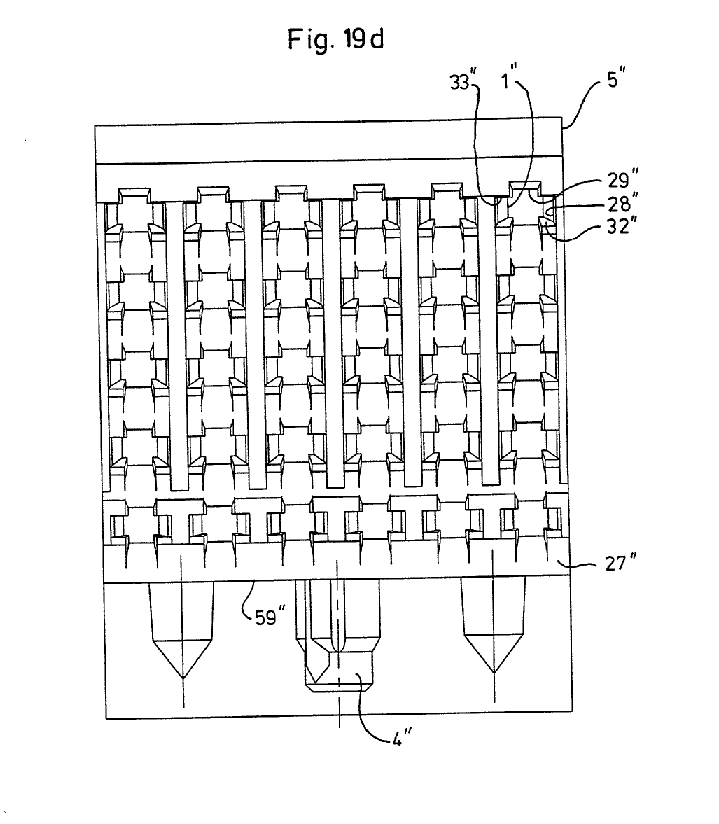

FIG. 19a shows a pin connector 5″ in accordance with the present invention. All parts and components in this figure which correspond to those of the foregoing receptacle contact, are now referenced using the original numbers with a double prime (″) assigned to it; other than that, the part numbers remain unaltered. FIG. 19b shows a front view of a similar connector but in which all cavities 1″ comprise a pin terminal 2″. The pin terminal 2″ in FIG. 19a is shown to have pin portion 60 which, at a twisted, flexible hinge portion 14″, is rotated through 45° with respect to the tail portion 15″. Within retention portion 31″ of the cavity 1″, the pin terminal is fixedly accommodated in a similar way as the receptacle terminals of the present invention. In the front portion 34″ of the cavity 1″the pin terminal 2″ is floating, thus, providing more flexibility when cooperating with a mating receptacle terminal, the latter being either flexible itself or not.

In the front view of the plug connector, observed from the pin (to receptacle) mating sides shown in FIG. 19b, the upper three rows are shown to comprise pin terminals rotated through 45°, whereas the lower two rows comprise pin terminals which are not rotated at all.

Although only a 45°rotation is shown in FIGS. 19a and 19b, rotations through any angle, including 0°, are believed to be within the scope of the present invention.

FIG. 19c shows a cross section through the connector shown in FIG. 19b along line XIXc-XIXc. In FIG. 19c one can easily see that the pin portions 60 are floating within cavities 1′.

FIG. 19d shows a rear view of a connector housing 5″ for the plug connector shown in FIGS. 19a-19c. At the rear side, one can see the opening 29″through which the pin portion 60 must freely pass when inserting the pin terminal into cavity 1″, and opening 28″ which is shaped such that it fixedly clamps retention portion 16″ after insertion of terminal 2″.

FIG. 19e shows a cross section through a cavity 1″ of a terminal 5″ with a pin terminal 2″ without any rotation. The pin terminal 2″ is shown with a circular protrusion 61 used to guide the pin terminal 2″ in the first opening 29 (not shown in FIG. 19c) and thus to define the proper positioning of the floating pin portion within the front portion 34″ of cavity 1″.

Although FIGS. 19a-19e show connectors for right-angle application, it is envisaged that the present invention also relates to straight plug connectors with floating pin terminals, which can be provided with barbs (line 30″ in FIG. 19a) and/or lobes (like 24 in FIG. 10a).

FIG. 20 shows several pin connectors and receptacle connectors according to the invention intended to cooperate with one another. Pin connector 70 has right-angle terminals 2″ and is connected to a printed circuit board 71. Pin connector 70 is shown to cooperate with a receptacle connector 72 with straight receptacle terminals 2. The straight receptacle terminals 2 are provided with a contact portion 45 subdivided into a first contact portion extending through and contacting plated through holes of a printed circuit board 73. The first contact portions are extended with second contact portions which are shown to be designed as pin terminals of a plug connector 74. These latter pin terminals can cooperate with receptacle terminals of a mating connector 75, which is shown to be a straight connector connected to a printed circuit board 76.

At its rear side, connector 70 is provided with contact portions 45 with first contact portions contacting plated through holes of printed circuit board 71, and second contact portions designed as pin terminals of a plug connector 80. Plug connector 80 mates with a further connector 83 which is also designed with contact portions 45 for rear-plug-up application. To this end, these contact portions 45 have pin terminals within a separate housing forming plug connector 82 connected to printed circuit board 81. At its edge, the printed circuit board 73 is provided with a right-angle receptacle connector 77 which is allowed to cooperate with a right-angle pin connector 78 connected to a printed circuit board 79.

The connectors shown in FIG. 20 are all designed in accordance with the present invention, i.e., they are provided with floating terminals within the cavities 1, 1″ within the housings 5, 5″. Thus, they allow for correction of any misalignments of terminals within the cavities, as explained above.

While the present invention has been described in connection with the preferred embodiments of the various figures, it is to be understood that other similar embodiments may be used or modifications and additions may be made to the described embodiment for performing the same function of the present invention without deviating therefrom. Therefore, the present invention should not be limited to any single embodiment, but rather construed in breadth and scope in accordance with the recitation of the appended claims.

For instance, if any rotation is applied it is not necessarily applied in hinge 14 but, alternatively, the retention portion 16 itself may be rotated. Even a rotation in the contact portion 45 is considered to fall within the scope of the present invention.

What is claimed is:

1. A connector, comprising:
at least one housing, having at least one cavity with a retention portion, said retention portion including, in cross section, a first opening and a second opening; and
at least one terminal associated with said at least one cavity and including:
a mating section for interacting with a terminal of a mating connector and adapted to pass through said first opening in said retention portion of said cavity during insertion of said terminal into said housing;
a retention section angled relative to said mating section and securable within said second opening of said retention portion of said cavity;
an intermediate section located between said mating section and said retention section; and
a mounting section extending from said retention section.

2. The connector as recited in claim 1, wherein said intermediate section includes a first twisted section.

3. The connector as recited in claim 2, wherein said first twisted section turns an angle of approximately 45° or approximately 90°.

4. The connector as recited in claim 2, wherein said first opening has a plane of symmetry and said second opening has a plane of symmetry intersecting said plane of symmetry of said first opening.

6. The connector as recited in claim 2, wherein said retention section includes a second twisted section.

7. The connector as recited in claim 6, wherein said second twisted section turns an angle of approximately 45° or approximately 90°.

8. The connector as recited in claim 1, wherein said intermediate section includes a folded section disposed at an angle.

9. The connector as recited in claim 8, wherein said angle of said folded section is approximately 45° or approximately 90°.

10. The connector as recited in claim 8, wherein said first opening has a plane of symmetry and said second opening has a plane of symmetry intersecting said plane of symmetry of said first opening.

11. The connector as recited in claim 1, wherein said retention section includes at least one barb.

12. The connector as recited in claim 11, wherein said second opening includes a side wall, said at least one barb pressable into said side wall.

13. The connector as recited in claim 1, wherein said at least one cavity has an axis of symmetry, said second opening having a bottom wall angled with respect to said axis of symmetry so that a cross-sectional dimension of said second opening decreases from a rear to a mating end of the connector.

14. The connector as recited in claim 13, wherein said retention section includes at least one barb for pressing into said bottom wall of said second opening.

15. The connector as recited in claim 1, wherein the connector is a right angle connector having a mating end and an open rear end inclined relative to said mating end, said housing having a plurality of cavities arranged in an array of rows and columns.

16. The connector as recited in claim 1, wherein the connector is a straight-type connector having a mating end and a rear end, said at least one terminal including a lobe for abutting said rear end.

17. The connector as recited in claim 1, wherein said mating section comprises a pin or a tuning fork.

18. The connector as recited in claim 1, wherein said at least one housing comprises a plurality of housings arranged in a parallel relationship and connected together by a strip.

19. The connector as recited in claim 1, wherein said mounting section includes:
a first section extending from said retention section and being one of a press-fit, through hole mount, hold down and surface mount type contact; and
a second section extending from said first section and being one of a pin and wire-wrap type contact.

20. The connector as recited in claim 1, wherein said cavity, in cross section, has a cruciform shape.

21. A terminal, comprising:
a mating section for interacting with a terminal of a mating connector and adapted to pass through a cavity in a housing of a connector during insertion of the terminal into the housing;
a retention section angled relative to said mating section and securable within the cavity in the housing of the connector;
an intermediate section located between said mating section and said retention section; and
a mounting section extending from said retention section.

22. The terminal as recited in claim 21, wherein said intermediate section includes a first twisted section.

23. The terminal as recited in claim 22, wherein said first twisted section turns an angle of approximately 45° or approximately 90°.

24. The terminal as recited in claim 22, wherein said retention section includes a second twisted section.

25. The terminal as recited in claim 24, wherein said second twisted section turns an angle of approximately 45° or approximately 90°.

26. The terminal as recited in claim 21, wherein said intermediate section includes a folded section disposed at an angle.

27. The terminal as recited in claim 26, wherein said angle of said folded section is approximately 45° or approximately 90°.

28. The terminal as recited in claim 21, wherein said retention section includes at least one barb.

29. The terminal as recited in claim 21, wherein said mating section comprises a pin or a tuning fork.

30. The terminal as recited in claim 21, wherein said mounting section includes:
a first section extending from said retention section and being one of a press-fit, through hole mount, hold down and surface mount type contact; and
a second section extending from said first section and being one of a pin and wire-wrap type contact.

31. A connector, comprising:
a plurality of modules; and
a strip engaging said modules for maintaining said modules in parallel relationship.

32. The connector as recited in claim 31, wherein said strip is generally flat.

33. The connector as recited in claim 31, wherein said strip includes a structure for latching said plurality of modules.

34. A terminal, comprising:
a mating portion for interacting with a terminal of a mating connector along a mating axis;
a mounting portion for interacting with a substrate; and
a retention portion between said mating and mounting portions for securing the terminal within a cavity of a connector housing and including at least two barbs angled relative to said mating axis.

35. The terminal as recited in claim 34, further comprising a nick allowing bending of said mounting portion relative to said retention portion, wherein said barbs are located near said nick.

36. A terminal positionable within a cavity of a housing of a connector, comprising:
a mating portion for interacting with a terminal of a mating connector and defining a plane;
a mounting portion for interacting with a substrate; and
at least one lobe extending from said plane for limiting the depth of insert of the terminal within the cavity of the housing of the connector.

37. The terminal as recited in claim 36, wherein said at least one lobe comprises two lobes extending in opposite directions from said plane.

38. The terminal as recited in claim 37 in combination with a connector having a rear end, wherein at least one of said lobes abuts said rear end of said connector.
